(19) United States
(12) Patent Application Publication
(10) Pub. No.: US 2026/0066248 A1
(43) Pub. Date: Mar. 5, 2026

(54) SPUTTERING APPARATUS AND SPUTTERING METHOD

(71) Applicant: Japan Display Inc., Tokyo (JP)

(72) Inventor: Arichika ISHIDA, Tokyo (JP)

(73) Assignee: Japan Display Inc., Tokyo (JP)

(21) Appl. No.: 19/382,357

(22) Filed: Nov. 7, 2025

Related U.S. Application Data
(63) Continuation of application No. PCT/JP2024/018540, filed on May 20, 2024.

(30) Foreign Application Priority Data
Jun. 13, 2023 (JP) 2023-097073

(51) Int. Cl. H01J 37/34; C23C 14/34; H10H 20/01

(52) U.S. Cl. CPC H01J 37/3417; C23C 14/3407; C23C 14/3464; H01J 37/3426; H01J 37/3441; H10H 20/01335; H01J 2237/332

(57) ABSTRACT

A sputtering apparatus includes: a substrate hold portion configured to hold a substrate; a first target facing the substrate hold portion; a second target facing the substrate hold portion and arranged side by side with the first target; and a partition wall between the first target and the second target, wherein each of a first normal line in an arbitrary position of the first target and a second normal line in an arbitrary position of the second target is connected to an arbitrary point on the substrate.

### CROSS REFERENCE TO RELATED APPLICATIONS

This application is a Continuation of International Patent Application No. PCT/JP2024/018540, filed on May 20, 2024, which claims the benefit of priority to Japanese Patent Application No. 2023-097073 filed on Jun. 13, 2023, the entire contents of which are incorporated herein by reference.

### FIELD

An embodiment of the present invention relates to a sputtering apparatus and a sputtering method. In particular, an embodiment of the present invention relates to a sputtering apparatus and a sputtering method using a rotary target.

### BACKGROUND

In small and medium sized display devices such as smartphones, display devices using liquid crystal or OLED's (Organic Light-emitting Diode) have already been commercialized. Among these, an OLED display device using OLED's, which is a self-luminous element, has the advantage of having high contrast and not requiring a backlight, as compared with a liquid crystal display device. However, since an OLED is composed of an organic compound, it is difficult to ensure high reliability of the OLED display device due to degradation of the organic compound.

In recent years, as a next-generation display device, a so-called micro LED display device or mini LED display device in which a minute LED chip is mounted in a pixel of a circuit substrate has been developed. An LED is a self-luminous element similar to an OLED. However, unlike OLED's, an LED is composed of a stable inorganic compound including gallium (Ga) or indium (In). Therefore, compared with an OLED display device, it is easy to ensure a micro LED display device having high reliability. In addition, an LED chip has high luminous efficiency and can realize high brightness. Therefore, the micro LED display device or mini LED display device is expected to be a next-generation display device with high reliability, high brightness, and high contrast.

Incidentally, a gallium nitride film used in the micro LED and the like is generally deposited on a sapphire substrate at a high temperature of 800° C. to 1000° C. using MOCVD (Metal Organic Chemical Vapor Deposition) or HVPE (Hydride Vapor Phase Epitaxy). However, in recent years, a method for depositing a gallium nitride film by sputtering, which enables deposition at relatively low temperatures, has been developed (for example, see Japanese laid-open patent publication No. 2012-119569).

### SUMMARY

A sputtering apparatus according to an embodiment of the present invention includes: a substrate hold portion configured to hold a substrate; a first target facing the substrate hold portion; a second target facing the substrate hold portion and arranged side by side with the first target; and a partition wall between the first target and the second target, wherein each of a first normal line in an arbitrary position of the first target and a second normal line in an arbitrary position of the second target is connected to an arbitrary point on the substrate.

A sputtering apparatus according to an embodiment of the present invention includes: a substrate hold portion configured to hold a substrate; a first target facing the substrate hold portion and attached with a first target member; and a second target facing the substrate hold portion, arranged side by side with the first target and attached with a second target member different from the first target member, wherein the first target member contains gallium.

A sputtering method according to an embodiment of the present invention includes: holding a substrate to a substrate hold portion facing a first target and a second target; forming a stacked structure including a first material of the first target and a second material of the second target by:
depositing the first material of the first target to the substrate by moving the first target and the substrate hold portion relatively while generating plasma for the first target in a first step; and depositing the second material of the second target to the substrate by moving the second target and the substrate hold portion relatively while generating plasma for the second target in a second step.

### BRIEF DESCRIPTION OF DRAWINGS

FIG. 1 is a diagram showing an overview of a sputtering apparatus according to an embodiment of the present invention.

FIG. 2 is a flowchart showing a sputtering method according to an embodiment of the present invention.

FIG. 3A is a diagram illustrating a sputtering method according to an embodiment of the present invention.

FIG. 3B is a diagram illustrating a sputtering method according to an embodiment of the present invention.

FIG. 4 is a cross-sectional view showing a semiconductor device manufactured using a sputtering method according to an embodiment of the present invention.

FIG. 5 is a flowchart showing a modification of a sputtering method according to an embodiment of the present invention.

FIG. 6A is a diagram illustrating a modification of a sputtering method according to an embodiment of the present invention.

FIG. 6B is a diagram illustrating a modification of a sputtering method according to an embodiment of the present invention.

FIG. 7 is a diagram showing an overview of a modification of a sputtering apparatus according to an embodiment of the present invention.

FIG. 8A is a diagram illustrating a sputtering method according to an embodiment of the present invention.

FIG. 8B is a diagram illustrating a sputtering method according to an embodiment of the present invention.

FIG. 8C is a diagram illustrating a modification of a sputtering method according to an embodiment of the present invention.

FIG. 9 is a diagram showing an overview of a sputtering apparatus according to an embodiment of the present invention.

FIG. 10 is a diagram showing an overview of a modification of a sputtering apparatus according to an embodiment of the present invention.

FIG. 11A is a diagram illustrating an overview of a sputtering apparatus and a sputtering method according to an embodiment of the present invention.

FIG. 11B is a diagram illustrating an overview of a sputtering apparatus and a sputtering method according to an embodiment of the present invention.

FIG. 11C is a diagram illustrating an overview of a sputtering apparatus and a sputtering method according to an embodiment of the present invention.

FIG. 12 is a cross-sectional view showing a semiconductor device manufactured using a sputtering method according to an embodiment of the present invention.

FIG. 13 is a diagram showing an overview of a sputtering apparatus according to an embodiment of the present invention.

FIG. 14 is a cross-sectional view showing a light-emitting element manufactured using a sputtering method according to an embodiment of the present invention.

### DESCRIPTION OF EMBODIMENTS

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In the drawings, the widths, thicknesses, shapes, and the like of the respective portions may be schematically represented in comparison with actual embodiments to make the description clearer. However, the illustrated shapes are merely examples, and do not limit the interpretation of the present invention. In the present specification and the drawings, the same reference signs are given to elements similar to those previously described with respect to the previous drawings, and detailed description thereof may be omitted as appropriate.

In the embodiments of the present invention, a direction from a first member toward a second member is referred to as “on” or “above.” Conversely, a direction from the second member toward the first member is referred to as “under” or “below.” In this way, for convenience of explanation, the phrase “above” or “below” is used for description, but for example, the first member and the second member may be arranged so that the vertical relationship is opposite to that shown in the figure. In the following explanation, for example, the expression “the second member on the first member” merely describes the vertical relationship between the first member and the second member as described above, and another member may be arranged between the first member and the second member. Above or below means a stacking order in a structure in which a plurality of layers is stacked, and the expression “the second member above the first member” may be a positional relationship in which the first member and the second member do not overlap in a plan view. On the other hand, the second member vertically above the first member indicates a positional relationship in which the first member and the second member overlap each other in a plane view.

In the present specification, the terms “film” and “layer” can optionally be interchanged with one another.

Furthermore, in the present specification, the expressions “a includes A, B or C,” “a includes any of A, B and C,” and “a includes one selected from a group consisting of A, B, and C” do not exclude the case where a includes a plurality of combinations of A to C unless otherwise specified. Furthermore, these expressions do not exclude the case where a includes other elements.

In addition, the following embodiments can be combined as long as there is no technical contradiction.

If a film forming a micro LED of a gallium nitride film can be deposited at a low temperature, the micro LED can be directly formed on a glass substrate. The micro LED is formed by stacking a plurality of films having differing compositions. In a conventional sputtering apparatus, it is necessary to prepare a target and a chamber for films having different compositions.

An object of an embodiment of the present invention is to provide a new sputtering apparatus and sputtering method in view of the above problem.

### 1. First Embodiment

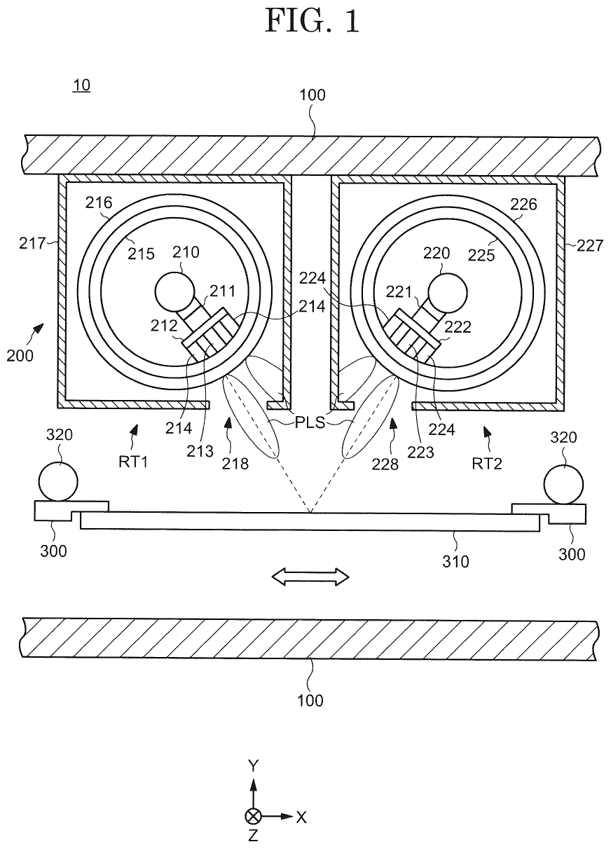

A sputtering apparatus 10 according to an embodiment of the present invention, a sputtering method using the sputtering apparatus 10, and a semiconductor device 20 formed by the sputtering method will be described with reference to FIG. 1 to FIG. 4.

### [1-1. Configuration of Sputtering Apparatus 10]

FIG. 1 is a diagram showing an overview of a sputtering apparatus according to an embodiment of the present invention. FIG. 1 is a top view of the sputtering apparatus 10. As shown in FIG. 1, the sputtering apparatus 10 includes a chamber 100, a target portion 200, and a substrate hold portion 300. In FIG. 1, a portion of the chamber 100 is shown. The chamber 100 forms a closed space. Although not shown, an exhaust port and a process gas supply port are provided in the chamber 100. The pressure inside the chamber 100 can be reduced through the exhaust port. Gases such as argon and nitrogen required for sputtering can be supplied into the chamber 100 via the process gas supply port. A substrate 310 to be deposited is held by the substrate hold portion 300. In the example of FIG. 1, the substrate 310 is held by the substrate hold portion 300 so that the main surface of the substrate 310 expands in an X-axis direction and a Z-axis direction. In other words, the substrate 310 is held in the substrate hold portion 300 in the vertical position.

The target portion 200 includes rotary targets RT1 and RT2 arranged side by side to face the substrate hold portion 300. The rotary targets RT1 and RT2 include support members 210 and 220, fixing members 211 and 221, yokes 212 and 222, central magnets 213 and 223, peripheral magnets 214 and 224, backing tubes 215 and 225, and targets 216 and 226, respectively. The rotary targets RT1 and RT2 are surrounded by shielding plates 217 and 227. Each of the above members forming the rotary targets RT1 and RT2 has a shape that extends in a direction Z. The rotary targets RT1 and RT2 are arranged spaced apart in the direction X. The rotary target RT1 may be referred to as a “first target.” The rotary target RT2 may be referred to as a “second target.”

The support members 210 and 220 are rotatably fixed to the chamber 100. The fixing members 211 and 221 are connected to the support members 210 and 220 and extend from the support members 210 and 220 toward the backing tubes 215 and 225. The yokes 212 and 222 are fixed to end portions of the fixing members 211 and 221. The central magnets 213 and 223 and the peripheral magnets 214 and 224 are fixed to the yokes 212 and 222 and extend from the yokes 212 and 222 toward the backing tubes 215 and 225. End portions of the central magnets 213 and 223 and the peripheral magnets 214 and 224 on the backing tubes 215 and 225 sides have a curved shape along the inner walls of the backing tubes 215 and 225.

The central magnets 213 and 223 and the peripheral magnets 214 and 224 have a linear shape extending in the Z direction. The central magnets 213 and 223 and the peripheral magnets 214 and 224 rotate about the support members 210 and 220 along the inner walls of the backing tubes 215 and 225. The support members 210 and 220 are fixed to the fixing members 211 and 221 and rotate with the central magnets 213 and 223 and the peripheral magnets 214 and 224. However, the support members 210 and 220 may be fixed to the chamber 100 without rotating. In this case, the fixing members 211 and 221 are rotatably connected to the support members 210 and 220.

The targets 216 and 226 are fixed to the backing tubes 215 and 225. The backing tubes 215 and 225 and the targets 216 and 226 have a cylindrical shape about an axis extending in the direction Z, and rotate about the support member 210 and 220. The targets 216 and 226 rotate independently of the central magnets 213 and 223 and the peripheral magnets 214 and 224. In the following description, when the central magnet 213 and the peripheral magnet 214 are not specifically distinguished, and when the central magnet 223 and the peripheral magnet 224 are not specifically distinguished, they may be simply referred to as “magnets.”

As shown in FIG. 1, positions of the magnets that can be formed with respect to the substrate 310 may be referred to as “deposition positions.” In other words, when the positions of the magnets are the deposition positions, a plasma region PLS generated for the rotary targets RT1 and RT2 spreads out of the shielding plates 217 and 227 via slits 218 and 228, which will be described later. On the other hand, positions of the magnets that cannot be formed with respect to the substrate 310 may be referred to as “non-deposition positions.” In other words, when the positions of the magnets are the non-deposition positions, the plasma region PLS generated for the rotary targets RT1 and RT2 is shielded by the shielding plates 217 and 227, and does not spread out.

Gallium, gallium nitride, aluminum, aluminum nitride, indium, indium nitride, silicon, and silicon nitride are used as the targets 216 and 226. A material in which an impurity (dopant) is introduced into the above materials may be used as the targets 216 and 226. For example, a material in which magnesium or silicon is introduced as the dopant for gallium nitride may be used. Gallium nitride containing magnesium as the dopant functions as a P-type semiconductor. Gallium nitride containing silicon as the dopant functions as an N-type semiconductor.

The target 216 and the target 226 are different materials. For example, gallium nitride is used as the target 216, and aluminum nitride is used as the target 226. Alternatively, gallium nitride is used as the target 216, and indium nitride is used as the target 226. Alternatively, intrinsic gallium nitride is used as the target 216, and gallium nitride into which a dopant is introduced is used as the target 226. Intrinsic means that no dopant is intentionally introduced.

The central magnets 213 and 223 have different polarities from the peripheral magnets 214 and 224. That is, these magnets form a magnetic field from the central magnets 213 and 223 toward the peripheral magnets 214 and 224 (or toward the opposite direction). This magnetic field confines electrons in the plasma, so that the high-density plasma region PLS is formed in a region corresponding to the regions between the central magnets 213 and 223 and the peripheral magnets 214 and 224. In the plasma region PLS, argon introduced as the process gas is ionized. The ionized argon is accelerated toward the targets 216 and 226 in a sheath region formed between the plasma region PLS and the target 216 and between the plasma region PLS and the target 226. The argon accelerated in this way collides with the targets 216 and 226, and the target material is sputtered.

As discussed above, the sputtered target material may fly from the surfaces of the targets 216 and 226 toward the plasma region PLS. In FIG. 1, the dotted lines passing through the plasma region PLS from the surfaces of the targets 216 and 226 to the substrate 310 are the trajectories of the target material to be sputtered. As a result of the above sputtering, the target material is deposited on the substrate 310 around the position where the dotted lines reach the substrate 310. The centers of each of the support members 210 and 220 are positioned on the extensions of the dotted lines. That is, the dotted lines are normal lines on an arbitrary surface of the targets 216 and 226. The dotted line extending from the target 216 toward the substrate 310 may be referred to as a “first normal line.” The dotted line extending from the target 226 toward the substrate 310 may be referred to as a “second normal line.” Each of the first and second normal lines is connected to any point on the substrate 310. In other words, the targets 216 and 226 are arranged so that the target material sputtered therefrom is deposited at the same point on the substrate 310.

The shielding plates 217 and 227 are provided with the slits 218 and 228. The shielding plates 217 and 227 continuously surround the peripheries of the targets 216 and 226 except for the regions where the slits 218 and 228 are provided. The slit 218 is provided on the rotary target RT2 side with respect to a line passing through the rotational axis of the rotary target RT1 among normal lines with respect to the surface of the substrate hold portion 300 or the substrate 310. The slit 228 is provided on the rotary target RT1 side of lines perpendicular to the surface of the substrate hold portion 300 or the substrate 310 and passing through the rotational axis of the rotary target RT2.

Portions of the shielding plates 217 and 227 sandwiched between the rotary targets RT1 and RT2 function as partition walls for suppressing the deposition of the target material sputtered from the rotary target RT1 on the rotary target RT2 and suppressing the deposition of the target material sputtered from the rotary target RT2 on the rotary target RT1. The portions functioning as the partition walls are provided to shield a space sandwiched between the rotary targets RT1 and RT2.

Portions of the shielding plate 217 positioned between the rotary target RT1 and the substrate hold portion 300 (or the substrate 310) suppress the target material sputtered from the rotary target RT1 from passing through the regions other than the slit 218 and deposited on the substrate 310. The portion may be referred to as a “first shielding plate.” A portion of the shielding plate 227 positioned between the rotary target RT2 and the substrate hold portion 300 (or the substrate 310) suppresses the target material sputtered from the rotary target RT2 from passing through the regions other than the slit 228 and deposited on the substrate 310. The portion may be referred to as a “second shielding plate.”

When expressed as described above, the first shielding plate corresponds to the portion of the shielding plate 217 that extends parallel to the surface of the substrate hold portion 300. The second shielding plate corresponds to the portion of the shielding plate 227 extending parallel to the surface of the substrate hold portion 300. The partition walls correspond to both or one of the portions of the shielding plates 217 and 227 that extend between the rotary targets RT1 and RT2 in the same direction as the normal lines to the surface of the substrate hold portion 300 or the substrate 310. In this case, it can be said that the first shielding plate and the second shielding plate are connected to the partition walls.

The substrate hold portion 300 is moved in a direction indicated by an arrow by a moving mechanism 320. For example, a roller in contact with the substrate hold portion 300 is provided as the moving mechanism 320. However, the moving mechanism 320 is not limited to the configuration shown in FIG. 1 as long as the substrate hold portion 300 holding the substrate 310 can be moved in the direction indicated by the arrow. Although the configuration in which the substrate hold portion 300 moves with respect to the target portion 200 has been exemplified in the present embodiment, the present invention is not limited to this configuration. For example, the position of the substrate hold portion 300 may be fixed, and the target portion 200 may move with respect to the substrate hold portion 300. That is, the substrate hold portion 300 can move with respect to the target portion 200.

### [1-2. Sputtering Method Using Sputtering Apparatus 10]

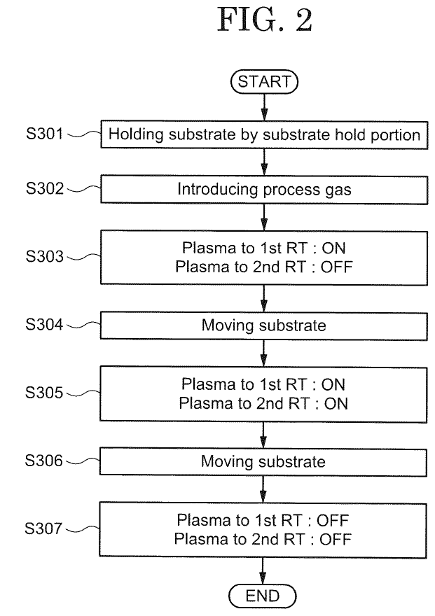

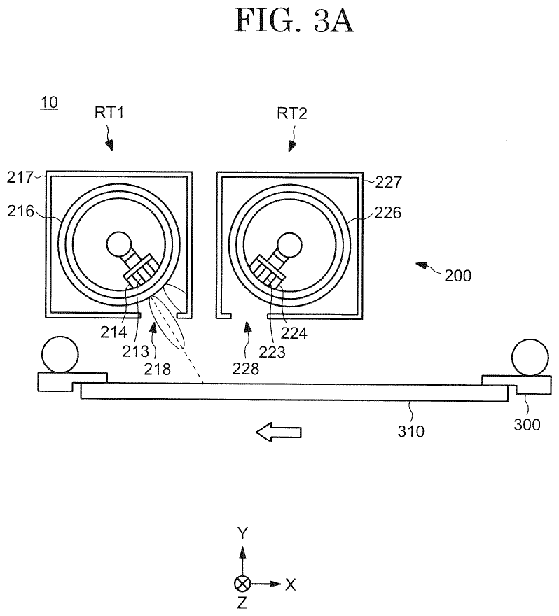

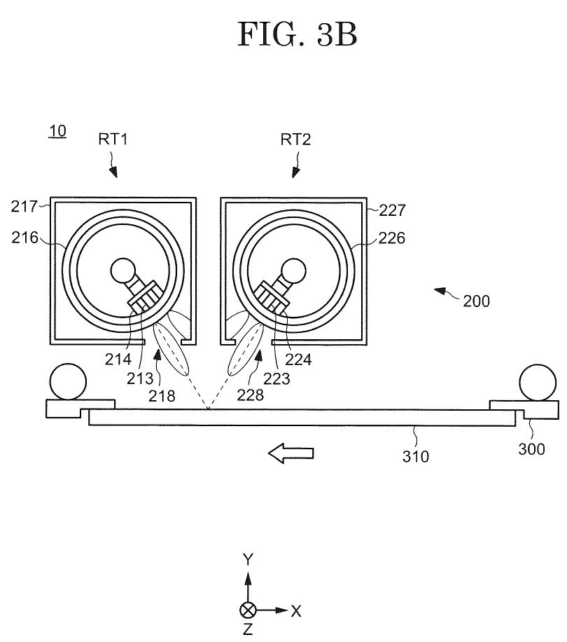

FIG. 2 is a flowchart showing a sputtering method according to an embodiment of the present invention. FIG. 3A and FIG. 3B are diagrams illustrating a sputtering method according to an embodiment of the present invention. A sputtering method using the sputtering apparatus 10 will be described with reference to these drawings. In FIG. 3A and FIG. 3B, the chamber 100 is omitted.

First, the substrate 310 is guided into the chamber and held in the substrate hold portion 300 (step S301; Holding substrate on substrate support unit). Subsequently, the pressure inside the chamber is reduced by evacuation using a vacuum pump or the like, and the process gas is introduced into the chamber (step S302; Introduction of process gas). After the introduction of the process gas, electric power is supplied to the rotary target RT1, and plasma is generated for the rotary target RT1 as shown in FIG. 3A (step S303; Plasma ON for first RT). In this case, since no electric power is supplied to the rotary target RT2, no plasma is generated for the rotary target RT2 (step S303; Plasma OFF for second RT). In this state, as shown in FIG. 3A, the substrate hold portion 300 holding the substrate 310 is moved in the direction indicated by the arrow (step S304; Substrate movement). A material (first material) of the target 216 attached to the rotary target RT1 is deposited on the substrate 310 by the step S304.

When the substrate hold portion 300 is moved in the direction of FIG. 3A and the deposition is completed to the end portion of the deposition region of the substrate 310, the substrate hold portion 300 moves in the direction opposite to the arrow. The above deposition may be continued during the movement in the opposite direction, or the deposition may not be performed by stopping the plasma.

Upon completion of the above movement in the opposite direction, the electric power is supplied to both of the rotary targets RT1 and RT2 and a plasma is generated for the rotary targets RT1 and RT2 (step S305; Plasma ON for the first RT, plasma ON for the second RT) as shown in FIG. 3B. In this state, the substrate hold portion 300 holding the substrate 310 is moved in the direction indicated by the arrow (step S306; Substrate movement). By the steps S305 and S306, the material of the target 216 attached to the rotary targets RT1 and RT2 and a material (second material) of the target 226 are deposited on the substrate 310. As a result, a compound composed of the materials of the targets 216 and 226 is deposited on the substrate 310.

By stopping the power supply to the rotary targets RT1 and RT2, the plasma generated for them is stopped (step S307; Plasma OFF for the first RT, plasma OFF for the second RT), and the supply of the process gas is stopped, thereby completing the above deposition process.

In the above sputtering method, although the configuration in which plasma is generated for both of the rotary targets RT1 and RT2 in step S305, and the material of each of the targets 216 and 226 is deposited on the substrate 310 is exemplified, the present invention is not limited to this configuration. For example, by generating only the plasma for the rotary target RT2 without generating the plasma for the rotary target RT1, only the material of the target 226 may be formed on the substrate 310.

### [1-3. Method for Manufacturing Semiconductor Device]

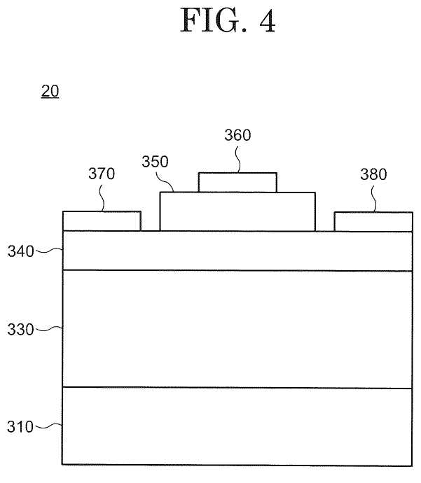

FIG. 4 is a cross-sectional view showing a semiconductor device manufactured using a sputtering method according to an embodiment of the present invention. When gallium nitride is used as the target 216 and aluminum nitride is used as the target 226, the semiconductor device 20 as shown in FIG. 4 can be manufactured by performing the above deposition process.

In the above configuration, when the deposition shown in steps S303 and S304 in FIG. 2 and FIG. 3A is performed, a gallium nitride layer (GaN layer) is deposited on the substrate 310. Subsequently, when the deposition shown in steps S305 and S306 in FIG. 2 and FIG. 3B is performed, a gallium nitride layer (aluminum gallium nitride layer; AlGaN layer) in which aluminum is introduced as a dopant is deposited on the substrate 310. By the above deposition, a stack of the AlGaN layer/GaN layer is formed on the substrate 310. That is, the deposition of the gallium nitride layer and the deposition of the aluminum gallium nitride layer can be continuously performed in the same chamber.

An example of the semiconductor device formed using the above deposition process is the semiconductor device 20 of FIG. 4. As shown in FIG. 4, the semiconductor device 20 is formed on the substrate 310. The semiconductor device 20 includes a first gallium nitride layer 330, a second gallium nitride layer 340, a gate insulating layer 350, a gate electrode 360, a source electrode 370, and a drain electrode 380.

An intrinsic GaN layer is formed as the first gallium nitride layer 330. An AlGaN layer is formed as the second gallium nitride layer 340. The first gallium nitride layer 330 functions as a channel for the semiconductor device 20. Aluminum oxide is formed as the gate insulating layer 350. For example, a typical metal material, such as aluminum, titanium, and molybdenum, is formed as the gate electrode 360, the source electrode 370, and the drain electrode 380.

By using the sputtering apparatus 10 and the deposition process described above, the layers having different compositions are deposited in the same chamber, and a stacked structure can be formed. For example, the AlGaN layer/GaN layer may be continuously formed in the same chamber 100 as the second gallium nitride layer 340 and the first gallium nitride layer 330. Therefore, it is possible to suppress dust and contaminants from adhering to the interface between the first gallium nitride layer 330 and the second gallium nitride layer 340 (the interface between the AlGaN layer/GaN layer). As a result, since the interface between the AlGaN layer/GaN can be kept clean, the semiconductor device 20 with high mobility and high reliability can be realized.

### [1-4. First Modification of Sputtering Method]

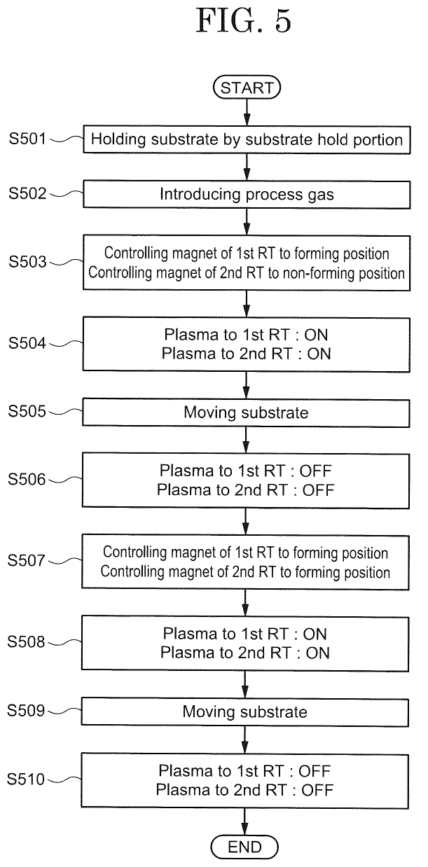

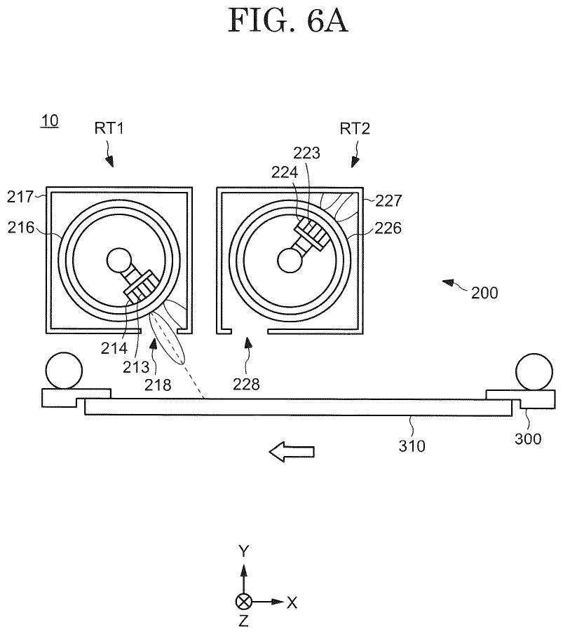

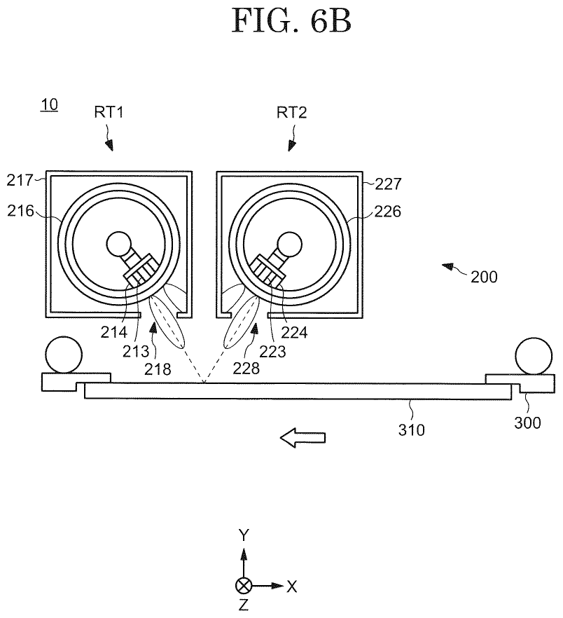

FIG. 5 is a flowchart showing a modification of a sputtering method according to an embodiment of the present invention. FIG. 6A and FIG. 6B are diagrams illustrating a modification of a sputtering method according to an embodiment of the present invention. A modification of the sputtering method using the sputtering apparatus 10 will be described with reference to these drawings. In FIG. 6A and FIG. 6B, the chamber 100 is omitted.

In FIG. 5, since steps S501 and S502 are the same as steps S201 and S202 in FIG. 2, the explanation thereof will be omitted. After the introduction of the process gas in step S502, as shown in FIG. 6A, the positions of the magnets of the rotary target RT1 (the central magnet 213 and the peripheral magnet 214) are controlled to the deposition position (step S503; Control the magnet of the first RT to the deposition position), the positions of the magnets of the rotary target RT2 (the central magnet 223 and the peripheral magnet 224) are controlled to the non-deposition position (step S503; Control the magnet of the second RT to the non-deposition position). In this state, electric power is supplied to the rotary targets RT1 and RT2, and plasma is generated for both of them (step S504: Plasma ON for the first RT, plasma ON for the second RT).

Through the above steps, plasma is generated for both of the rotary targets RT1 and RT2 as shown in FIG. 6A, but only the target material sputtered from the target 216 is deposited on the substrate 310. The target material sputtered from the target 226 travels in a direction opposite to the substrate 310 and is shielded by the shielding plate 227, so that the target material is not deposited on the substrate 310. In other words, plasma is generated at a position where the slit 218 is provided by controlling the magnet included in the rotary target RT1, and plasma is generated at a position where the slit 228 is not provided by controlling the magnet included in the rotary target RT2. In this state, the substrate hold portion 300 holding the substrate 310 moves in the direction indicated by the arrow (step S505; Substrate movement). By step S505, only the target 216 attached to the rotary target RT1 is deposited on the substrate 310.

When the substrate hold portion 300 is moved in the direction indicated by the arrow in FIG. 6A and the deposition is completed to the end portion of the deposition region of the substrate 310, the substrate hold portion 300 moves in the direction opposite to the arrow. The above deposition may be continued during the movement in the opposite direction, or the deposition may not be performed by stopping the plasma.

When the movement in the opposite direction is completed, the power supply to the rotary targets RT1 and RT2 is stopped when the deposition is performed during the movement in the opposite direction (step S506: Plasma OFF for the first RT, plasma OFF for the second RT), and as shown in FIG. 6B, the position of both magnets of the rotary targets RT1 and RT2 is controlled to the deposition position (step S507: Control magnets of the first RT to the deposition position, and control magnets of the second RT to the deposition position). In this state, electric power is supplied to the rotary targets RT1 and RT2, and plasma is generated for both of them (step S508: Plasma ON for the first RT, plasma ON for the second RT). In other words, by controlling the magnets included in the rotary targets RT1 and RT2, plasma is generated at the positions where the slits 218 and 228 are provided. In this state, the substrate hold portion 300 holding the substrate 310 is moved in the direction indicated by the arrow (step S509; Substrate movement). By steps S508 and S509, the materials of the target 216 and the target 226 attached to the rotary targets RT1 and RT2 are deposited on the substrate 310. As a result, the compound composed of the materials of the targets 216 and 226 is deposited on the substrate 310.

By stopping the power supply to the rotary targets RT1 and RT2, the plasma generated for them is stopped (step S510; Plasma OFF for the first RT, plasma OFF for the second RT), and the supply of the process gas is stopped, thereby completing the above deposition process.

Even in the sputtering method according to the above modification, similar to the sputtering method according to the first embodiment, layers having different compositions can be continuously formed in the same chamber 100.

### [1-5. Second Modification of Sputtering Method]

A method of adjusting a concentration of a dopant contained in a film to be deposited by using the sputtering apparatus 10 and the deposition process will be described. As described above, when gallium nitride is used as the target 216 and aluminum nitride is used as the target 226, the dopant concentration (aluminum concentration) in the AlGaN layer can be adjusted by adjusting the power supplied to the rotary targets RT1 and RT2. Specifically, by making the electric power supplied to the rotary target RT2 relatively smaller than the electric power supplied to the rotary target RT1, the aluminum concentration in the AlGaN layer can be reduced. Conversely, by making the electric power supplied to the rotary target RT2 relatively larger than the electric power supplied to the rotary target RT1, the aluminum concentration in the AlGaN layer can be increased.

In other words, the material used as the target 226 contains more dopants than the material used as the target 216. By adjusting the ratio between the electric power for generating plasma to the rotary target RT1 and the electric power for generating plasma to the rotary target RT2, a concentration of the dopant contained in the thin film formed on the substrate 310 is adjusted. Gallium nitride into which magnesium or silicon is introduced may be used as the target 226. For example, a concentration of the dopant contained in the material of the target 226 may be 1 time or more and 20 times or less of a concentration of the dopant contained in the thin film deposited on the substrate 310.

### [1-6. Modification of Sputtering Apparatus]

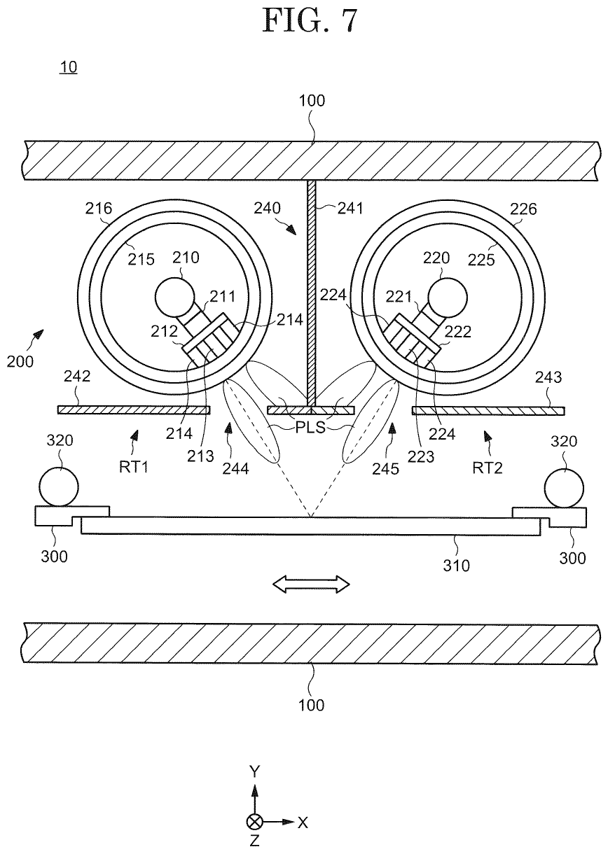

FIG. 7 is a diagram showing an overview of a modification of a sputtering apparatus according to an embodiment of the present invention. The sputtering apparatus 10 shown in FIG. 7 is similar to the sputtering apparatus 10 shown in FIG. 1, but the configuration of the shielding plate is different from that of the sputtering apparatus 10 shown in FIG. 1. Since the other configurations of FIG. 7 are the same as those of FIG. 1, the description will be omitted.

As shown in FIG. 7, a shielding plate 240 includes a partition 241, a first shielding plate 242, and a second shielding plate 243. The first shielding plate 242 is provided with a slit 244 at the same position as the slit 218 in FIG. 1. The second shielding plate 243 is provided with a slit 245 at the same position as the slit 228 in FIG. 1.

The partition wall 241 is provided between the rotary targets RT1 and RT2. The partition wall 241 is provided to shield the space sandwiched between the rotary targets RT1 and RT2. The partition wall 241 suppresses the target material sputtered from the rotary target RT1 from being deposited on the rotary target RT2, and suppresses the target material sputtered from the rotary target RT2 from being deposited on the rotary target RT1.

The first shielding plate 242 is provided between the rotary target RT1 and the substrate hold portion 300. The first shielding plate 242 suppresses the target material sputtered from the rotary target RT1 from passing through the region other than the slit 244 and deposited on the substrate 310. The second shielding plate 243 is provided between the rotary target RT2 and the substrate hold portion 300. The second shielding plate 243 suppresses the target material sputtered from the rotary target RT2 from passing through the region other than the slit 245 and deposited on the substrate 310.

Although a configuration in which the partition wall 241, the first shielding plate 242, and the second shielding plate 243 are provided as individual members is exemplified in FIG. 7, the present invention is not limited to this configuration. For example, at least two or more members of the partition wall 241, the first shielding plate 242, and the second shielding plate 243 may be integrally formed.

Even in the sputtering apparatus according to the above modification, similar to the sputtering apparatus according to the first embodiment, the layers having different compositions can be continuously formed in the same chamber 100. In addition, the first shielding plate 242 and the second shielding plate 243 may be omitted. Alternatively, the partition wall 241 may be omitted.

### 2. Second Embodiment

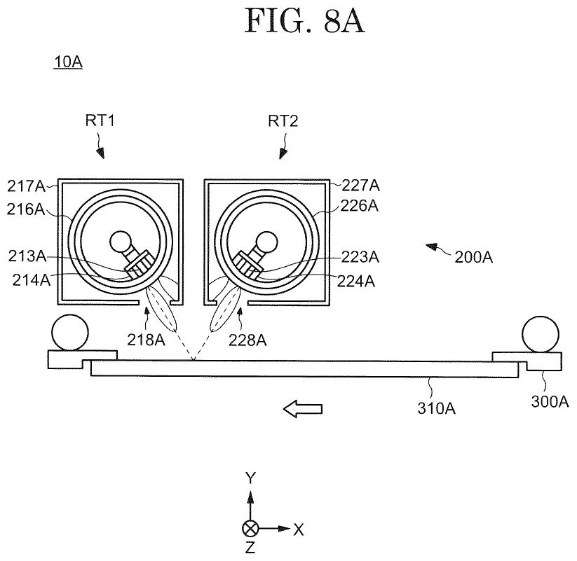

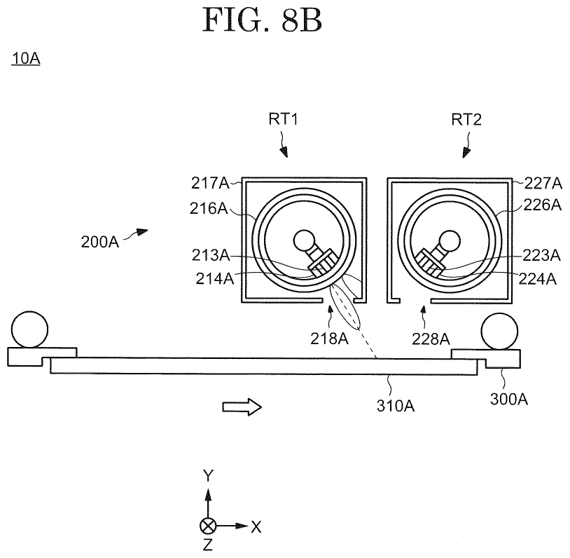

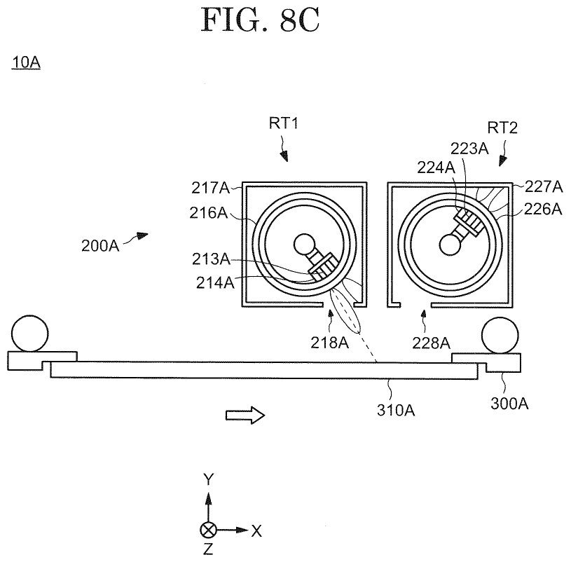

A sputtering method using a sputtering apparatus 10A according to an embodiment of the present invention will be described with reference to FIG. 8A and FIG. 8B. Since a configuration of the sputtering apparatus 10A used in the present embodiment is the same as that of the sputtering apparatus 10 shown in FIG. 1, the description will be omitted. In the present embodiment, an embodiment for forming a multi quantum well (MQW) structure of a gallium nitride layer (GaN layer) and an indium gallium nitride layer (InGaN layer) using the sputtering apparatus 10A will be described. In the following description, the description of the configurations similar to that of the sputtering apparatus 10 of the first embodiment in the configuration of the sputtering apparatus 10A is omitted, and configurations different from those of the sputtering apparatus 10 will be mainly described. In the following description, configurations similar to those of the first embodiment will be described with reference to FIG. 1 to FIG. 7, and a letter “A” is added to the signs shown in FIG. 1 to FIG. 7.

### [2-1. Sputtering Method Using Sputtering Apparatus 10A]

FIG. 8A to FIG. 8B are diagrams illustrating a sputtering method according to an embodiment of the present invention. In the present embodiment, gallium nitride is used as a target 216A, and indium nitride is used as a target 226A. In the following sputtering method, a GaN layer is formed in a first step and an InGaN layer is formed in a second step. The first step and the second step are alternately repeated to form an MQW structure in which the GaN layer and the InGaN layer are alternately stacked.

As shown in FIG. 8A, electric power is supplied to both of the rotary targets RT1 and RT2, and the plasmas for them are generated. Gallium nitride is sputtered from the rotary target RT1, and InN is sputtered from the rotary target RT2. As a result, the InGaN layer is deposited on a substrate 310A. In this state, a substrate hold portion 300A moves in the direction indicated by the arrow, and the InGaN layer is deposited on the entire substrate 310A. The electric power supplied to the rotary targets RT1 and RT2 and the moving speed of the substrate hold portion 300A are adjusted according to the thickness of the InGaN layer. The above operation may be referred to as the “first step.”

After the InGaN layer having a desired thickness is deposited during the operation shown in FIG. 8A, as shown in FIG. 8B, the supply of electric power for the rotary target RT2 is stopped while electric power is supplied to the rotary target RT1, so that plasma is generated only in the rotary target RT1. InN is not sputtered from the rotary target RT2, and gallium nitride is sputtered only from the rotary target RT1. As a result, the GaN layer is deposited on the substrate 310A. In this state, the substrate hold portion 300A moves in the direction indicated by the arrow, so that the GaN layer is deposited on the entire substrate 310A. The electric power supplied to the rotary target RT1 and the moving speed of the substrate hold portion 300A are adjusted according to the thickness of the GaN layer. The above operation may be referred to as the “second step.”

By repeating the first step and the second step described above, the MQW structure in which the InGaN layer and the GaN layer are repeatedly stacked is formed on the substrate 310A.

In the present embodiment, the method of depositing each layer by moving the substrate hold portion 300A in one direction in both of the first step and the second step has been exemplified, but the present invention is not limited to this method. For example, in the case where a desired thickness cannot be obtained by only moving in one direction, the substrate hold portion 300A may be moved back and forth one or more times in each of the first step and the second step.

Even if a plurality of different layers needs to be stacked repeatedly, such a stacked structure can be deposited in the same chamber by using the above sputtering apparatus 10A and the deposition process. According to the above sputtering method, it is possible to suppress dust and contaminants from adhering to the interface between the InGaN layer and the GaN layer. As a result, since the interface between the GaN layer and the InGaN layer can be kept clean, a semiconductor device with high mobility and high reliability can be realized.

### [2-2. Modification of Sputtering Method]

FIG. 8C is a diagram illustrating a sputtering method according to an embodiment of the present invention. A modification of the sputtering method according to the present embodiment will be described with reference to FIG. 8C. FIG. 8C is a diagram showing an alternative step of the second step of FIG. 8B. In the modification, since the first step is the same as the first step described above, the description will be omitted.

In the modification, as shown in FIG. 8C, electric power is supplied to both of the rotary targets RT1 and RT2 while the positions of the magnets (a central magnet 223A and a peripheral magnet 224A) of the rotary target RT2 are controlled to the non-deposition position. In this case, the InN sputtered from the rotary target RT2 is shielded by a shielding plate 227A, so that the InN is not deposited on the substrate 310A. As a result, only the GaN layer is deposited on the substrate 310A.

### 3. Third Embodiment

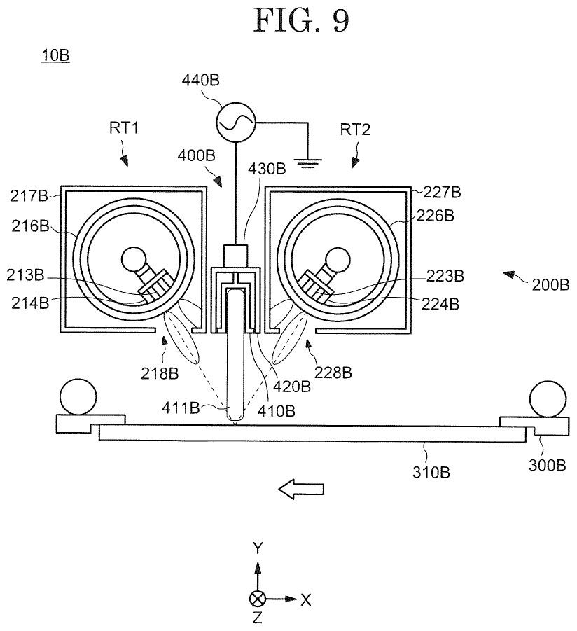

A sputtering method using a sputtering apparatus 10B according to an embodiment of the present invention will be described with reference to FIG. 9. A configuration of the sputtering apparatus 10B used in the present embodiment is similar to that of the sputtering apparatus 10 shown in FIG. 1, but the configuration is different from that of the sputtering apparatus 10 in that a line-shaped plasma source is provided between the rotary targets RT1 and RT2. In the following description, the description of configurations similar to those of the sputtering apparatus 10 of the first embodiment in the configuration of the sputtering apparatus 10B is omitted, and configurations different from those of the sputtering apparatus 10 will be mainly described. In the following description, configurations similar to those of the first embodiment will be described with reference to FIG. 1 to FIG. 7, and a letter “B” is added to the signs shown in FIG. 1 to FIG. 7.

### [3-1. Configuration of Sputtering Apparatus 10B]

As shown in FIG. 9, the sputtering apparatus 10B includes a plasma unit 400B that generates the line-shaped plasma between the rotary targets RT1 and RT2. The plasma unit 400B includes an electrode 410B, a housing 420B, a matching box 430B, and an RF power source 440B. The power source 410B is provided inside the housing 420B. The matching box 430B is provided between the RF power source 440B and the electrode 410B, and functions as a matcher for efficiently transmitting an RF signal transmitted from the RF power source 440B to the electrode 410B. The RF signal transmitted from the RF power source 440B is transmitted to the electrode 410B, thereby generating a linear plasma region 411B. The plasma region 411B extends from the electrode 410B toward a substrate 310B. In particular, in the present embodiment, the plasma region 411B extends from each of the rotary targets RT1 and RT2 toward a position where the trajectory (dotted line) of the target material to be sputtered reaches the substrate 310B.

In the case of FIG. 9, for example, gallium nitride is used as a target 216B of the rotary target RT1, and indium nitride is used as a target 226B. In addition, the plasma generated in the plasma region 411B is nitrogen plasma. In this case, the proportion of nitrogen with respect to gallium in the gallium nitride used as the target 216B is smaller than the proportion of nitrogen with respect to gallium in the GaN layer to be deposited. Similarly, the proportion of nitrogen with respect to indium in the InN used as the target 226B is smaller than the proportion of nitrogen with respect to indium in the InN layer to be deposited. Even when a target having such a composition is used, since the sputtered target material is nitrided by nitrogen plasma on the surface of the substrate 310B, the GaN layer and the InGaN layer having a desired ratio can be formed.

As described above, in the targets 216B and 226B, the electric resistance of the target can be reduced by making the proportion of nitride with respect to gallium and indium relatively small. In the sputtering apparatus, the target functions as a cathode. Therefore, by reducing the electric resistance of the target itself, the deposition rate by sputtering can be increased. A metal target of gallium or indium may be used as the targets 216B and 226B instead of gallium nitride or indium nitride.

According to the above configuration, a sputtering method similar to those in FIG. 8A to FIG. 8B can be performed. Therefore, effects similar to those of the second embodiment can be obtained by the present embodiment.

### [3-2. Modification of Sputtering Apparatus]

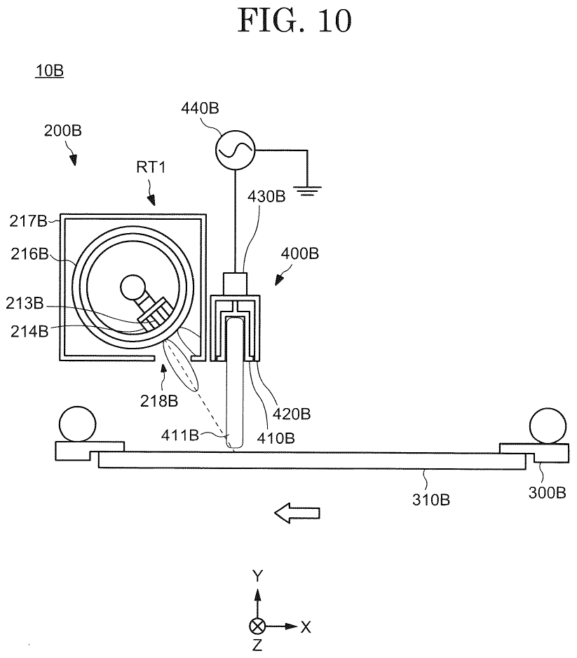

FIG. 10 is a diagram showing an overview of a modification of a sputtering apparatus according to an embodiment of the present invention. As shown in FIG. 10, the sputtering apparatus 10B may be formed by the rotary target RT1 and the plasma unit 400B. For example, gallium or gallium nitride is used as the target 216B. In the case where gallium nitride is used as the target 216B, the proportion of nitrogen with respect to gallium in gallium nitride is smaller than the proportion of nitrogen with respect to gallium in the GaN layer to be deposited. This configuration can improve the deposition rate of the GaN layer by sputtering.

### 4. Fourth Embodiment

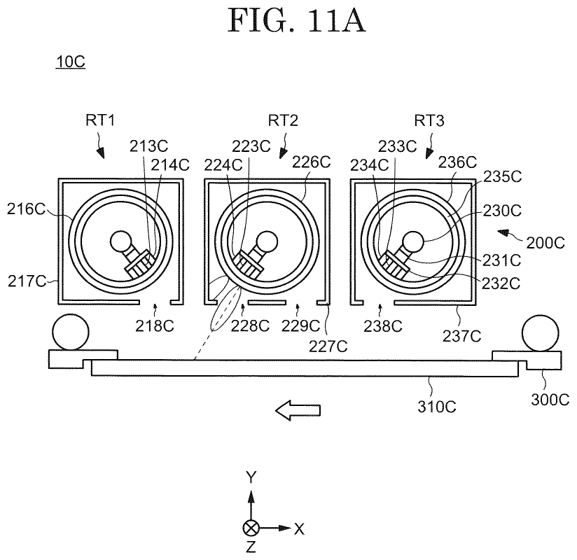

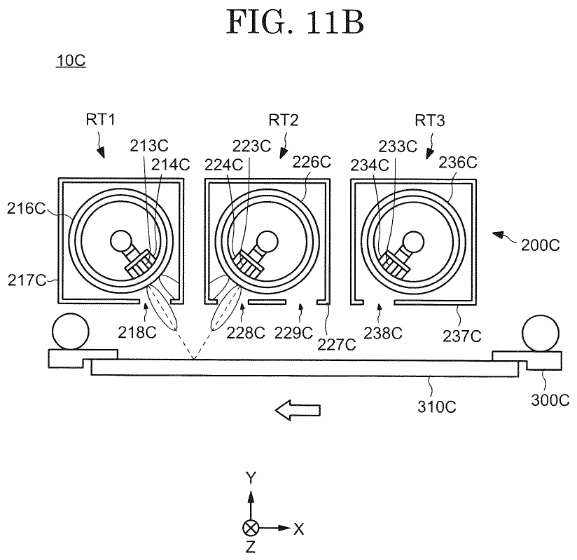

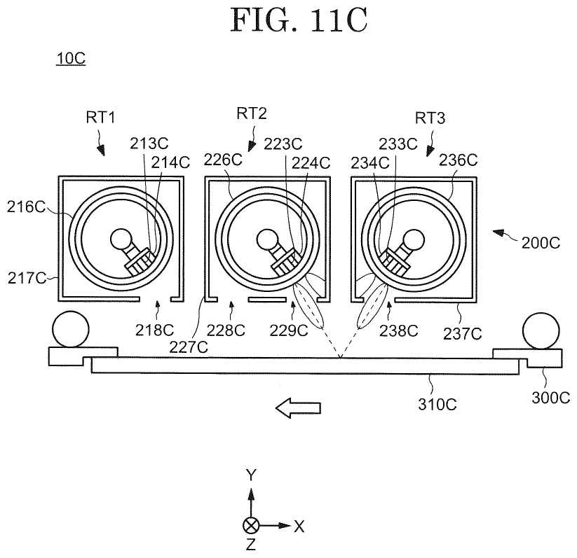

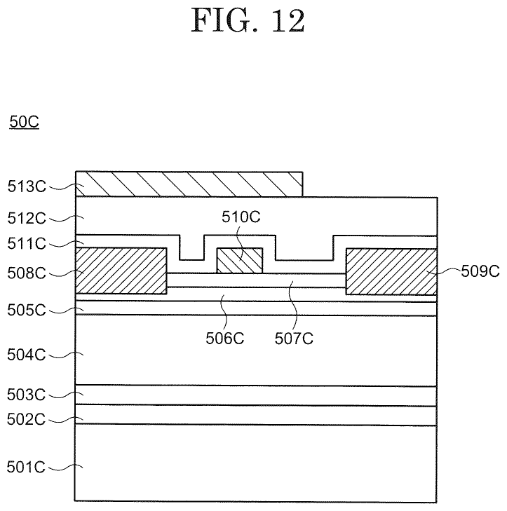

A sputtering method using a sputtering apparatus 10C according to an embodiment of the present invention and a semiconductor device 50C formed by the sputtering method will be described with reference to FIG. 11A to FIG. 12. A configuration of the sputtering apparatus 10C used in the present embodiment is similar to that of the sputtering apparatus 10 shown in FIG. 1, but the configuration is different from that of the sputtering apparatus 10 in that a rotary target RT3 is provided in addition to the rotary targets RT1 and RT2. In the following description, the description of configurations similar to those of the sputtering apparatus 10 of the first embodiment in the configuration of the sputtering apparatus 10C is omitted, and configurations different from those of the sputtering apparatus 10 will be mainly described. In the following description, configurations similar to those of the first embodiment will be described with reference to FIG. 1 to FIG. 7, and a letter “C” is added to the signs shown in FIG. 1 to FIG. 7.

### [4-1. Configuration of Sputtering Apparatus 10C]

As shown in FIG. 11A, the sputtering apparatus 10C has the rotary target RT3 in addition to the rotary targets RT1 and RT2. Similar to the rotary targets RT1 and RT2, the rotary target RT3 includes a support member 230C, a fixing member 231C, a yoke 232C, a central magnet 233C, a peripheral magnet 234C, a backing tube 235C, and a target 236C. The rotary target RT3 is surrounded by a shielding plate 237C. Each of the above members forming the rotary target RT3 has a shape that extends in the direction Z. The rotary target RT3 is arranged spaced apart from the rotary targets RT1 and RT2 in the direction X. Since each configuration of the rotary target RT3 is similar to each configuration of the rotary targets RT1 and RT2, detailed explanation thereof will be omitted.

A slit 218C is provided on the rotary target RT2 side with respect to a line passing through the rotational axis of the rotary target RT1 among normal lines with respect to a surface of a substrate hold portion 300C or a substrate 310C. The slit 238C is provided on the rotary target RT2 side with respect to a line passing through the rotational axis of the rotary target RT3 among normal lines with respect to the surface. A shielding plate 227C is provided with slits 228C and 229C. The slit 228C is provided on the rotary target RT1 side with respect to a line passing through the rotational axis of the rotary target RT2 among normal lines with respect to the surface. The slit 229C is provided on the rotary target RT3 side with respect to a line passing through the rotational axis of the rotary target RT2 among normal lines with respect to the surface.

The positions of the magnets (a central magnet 223C and a peripheral magnet 224C) of the rotary target RT2 are controllable. As shown in FIG. 11A and FIG. 11B, the positions of the magnets when the sputtered target material passes through the slit 228C and is deposited on the substrate 310C may be referred to as a “first deposition position.” As shown in FIG. 11C, the positions of the magnets when the sputtered target material passes through the slit 229C and is deposited on the substrate 310C may be referred to as a “second deposition position.”

### [4-2. Sputtering Method Using Sputtering Apparatus 10C]

FIG. 11A to FIG. 11C are diagrams illustrating a sputtering method according to an embodiment of the present invention. In the present embodiment, aluminum nitride (AlN) is used as a target 216C, gallium nitride is used as a target 226C, and magnesium-doped gallium nitride is used as the target 236C. Since the magnesium-doped gallium nitride functions as a P-type semiconductor, the gallium nitride layer may be referred to as a “p-GaN layer.” In the following sputtering method, a GaN layer is formed in the first step, an AlGaN layer is formed in the second step, and a p-GaN layer is formed in a third step. By executing the first step to the third step, a HEMT (High Electron Mobility Transistor) shown in FIG. 12 described later can be formed. A concentration of the dopant contained in the material of the target 236C is 1 time or more and 20 times or less of a concentration of the dopant contained in the thin film deposited on the substrate 310C.

As shown in FIG. 11A, electric power is supplied to the rotary target RT2 to generate plasma. Gallium nitride is sputtered from the rotary target RT2. As a result, a GaN layer is deposited on the substrate 310A. In this state, the substrate hold portion 300C moves in the direction indicated by the arrow, so that the GaN layer is deposited on the entire substrate 310C. The electric power supplied to the rotary target RT2 and the moving speed of the substrate hold portion 300C are adjusted according to the thickness of the GaN layer. The above operation may be referred to as the “first step.” Although the configuration in which the positions of the magnets of the rotary target RT2 are the first deposition position has been exemplified in FIG. 11A, the positions of the magnets may be the second deposition position.

After the GaN layer having a desired thickness is deposited during the operation in FIG. 11A, electric power is supplied to both of the rotary targets RT1 and RT2 as shown in FIG. 11B, so that plasmas for them are generated. In this case, the positions of the magnets of the rotary target RT2 are the first deposition position. Aluminum nitride is sputtered from the rotary target RT1, and gallium nitride is sputtered from the rotary target RT2. As a result, an AlGaN layer is deposited on the substrate 310C. In this state, the substrate hold portion 300C moves in the direction indicated by the arrow, so that the AlGaN layer is deposited on the entire substrate 310C. The electric power supplied to the rotary targets RT1 and RT2 and the moving speed of the substrate hold portion 300C are adjusted according to the thickness of the AlGaN layer. The above operation may be referred to as the “second step.”

After the AlGaN layer having a desired thickness is deposited during the operation in FIG. 11B, as shown in FIG. 11C, the positions of the magnets of the rotary target RT2 are switched to the second deposition position, and electric power is supplied to both of the rotary targets RT2 and RT3, so that plasmas for them are generated. Gallium nitride is sputtered from the rotary target RT2, and magnesium-containing gallium nitride is sputtered from the rotary target RT3. As a result, a p-GaN layer is deposited on the substrate 310C. The above operation may be referred to as the “third step.”

In the third step, by adjusting the ratio between the electric power for generating plasma to the rotary target RT2 and the electric power for generating plasma to the rotary target RT3, the concentration of the dopant contained in the thin film formed on the substrate 310C can be adjusted.

As described above, the p-GaN layer/AlGaN layer/GaN layer is formed by the first step to the third step shown in FIG. 11A to FIG. 11C. That is, according to the sputtering apparatus 10C of the present embodiment, for example, in a stacked structure such as the p-GaN layer/AlGaN layer/GaN layer, it is possible to suppress dust and contaminants from adhering to these interfaces.

Aluminum (Al) may be used as the target 216C. Gallium (Ga) may be used as the target 226C. A dopant concentration of the magnesium-containing gallium nitride used as the target 236C may be the same as the dopant concentration of the p-GaN layer formed on the substrate 310C, or may be higher than the dopant concentration of the p-GaN layer formed on the substrate 310C. The dopant concentration of the magnesium-containing gallium nitride used as the target 236C may be 1 time or more and 20 times or less of the dopant concentration of the p-GaN layer formed on the substrate 310C.

### [4-3. Semiconductor Device 50C Manufactured Using Sputtering Apparatus 10C]

FIG. 12 is a cross-sectional view showing a semiconductor device manufactured using a sputtering method according to an embodiment of the present invention.

As shown in FIG. 12, the semiconductor device 50C includes a substrate 501C, a barrier layer 502C, a buffer layer 503C, a GaN layer 504C, a first AlGaN layer 505C, a second AlGaN layer 506C, a third AlGaN layer 507C, a source electrode 508C, a drain electrode 509C, a gate electrode 510C, a first insulating layer 511C, a second insulating layer 512C, and a shield electrode 513C. The semiconductor device 50C is a so-called HEMT, but is not limited to this.

For example, a glass substrate or a quartz substrate can be used as the substrate 501C. For example, a silicon-nitride film or the like can be used as the barrier layer 502C. For example, an aluminum nitride film or the like can be used as the buffer layer 503C. An intrinsic gallium nitride layer can be used as the GaN layer 504C. An intrinsic aluminum gallium nitride layer can be used as the first AlGaN layer 505C. For example, a magnesium-doped aluminum gallium nitride layer can be used as the second AlGaN layer 506C. An intrinsic aluminum gallium nitride layer can be used as the third AlGaN layer 507C.

For example, a metal such as titanium or aluminum can be used as the source electrode 508C and the drain electrode 509C. For example, a metal material such as nickel or gold can be used as the gate electrode 510C. For example, a silicon nitride layer can be used as the first insulating layer 511C. For example, a silicon oxide layer can be used as the second insulating layer 512C. For example, a stacked metal material such as aluminum/titanium (Al/Ti) can be used as the shield electrode 513C. The barrier layer 502C may be omitted.

The semiconductor device 50C is manufactured as follows. First, a silicon nitride layer and an aluminum nitride layer are sequentially deposited on the substrate 501C to form the barrier layer 502C and the buffer layer 503C. Next, a gallium nitride layer, an aluminum gallium nitride layer, a magnesium-containing aluminum gallium nitride layer, and an aluminum gallium nitride layer are deposited on the buffer layer 503C to form the GaN layer 504C, the first AlGaN layer 505C, the second AlGaN layer 506C, and the third AlGaN layer 507C.

Subsequently, by a photolithography process, the third AlGaN layer 507C is etched to expose a portion of the second AlGaN layer 506C. The source electrode 508C and the drain electrode 509C are formed on the exposed second AlGaN layer 506C. The gate electrode 510C is formed on the third AlGaN layer 507C. A silicon nitride film and a silicon oxide film are sequentially deposited to cover the source electrode 508C, the drain electrode 509C, and the gate electrode 510C, and the first insulating layer 511C and the second insulating layer 512C are formed. The semiconductor device 50C can be formed by forming the shield electrode 513C on the second insulating layer 512C.

In the present embodiment, the sputtering apparatus 10C can be used to deposit the GaN layer 504C, the first AlGaN layer 505C, the second AlGaN layer 506C, and the third AlGaN layer 507C in the same chamber 100C. Therefore, it is possible to suppress dust and contaminants from adhering to these interfaces.

In addition, the semiconductor device 50C according to the present embodiment can be manufactured using, for example, a glass substrate, which has low heat resistance, because a gallium nitride film can be deposited using the sputtering apparatus 10C.

### 5. Fifth Embodiment

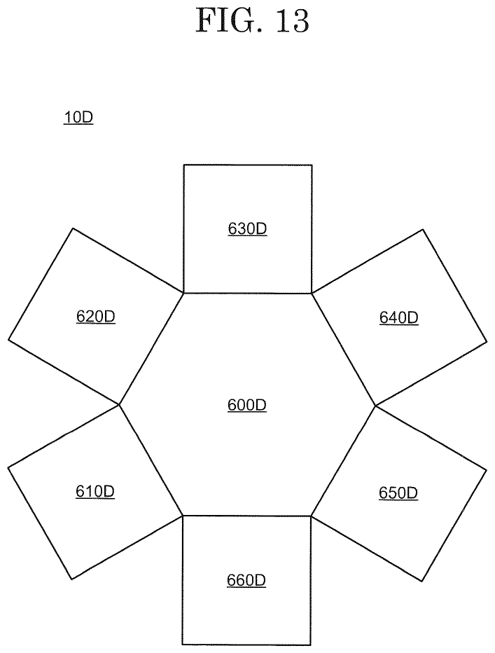

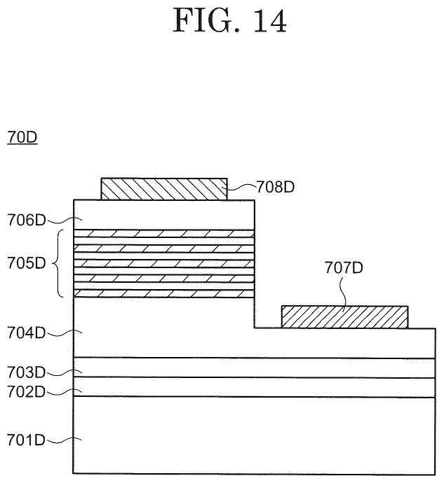

A sputtering apparatus 10D according to an embodiment of the present invention and a light-emitting element 70D formed using the sputtering apparatus 10D will be described with reference to FIG. 13 and FIG. 14. In the following description, the description of configurations similar to those of the sputtering apparatus 10 of the first embodiment in the configuration of the sputtering apparatus 10D is omitted, and configurations different from those of the sputtering apparatus 10 will be mainly described. In the following description, configurations similar to those of the first embodiment will be described with reference to FIG. 1 to FIG. 7, and a letter “D” is added to the signs shown in FIG. 1 to FIG. 7.

### [5-1. Configuration of Sputtering Apparatus 10D]

FIG. 13 is a diagram showing an overview of a sputtering apparatus according to an embodiment of the present invention. As shown in FIG. 13, the sputtering apparatus 10D includes a transfer chamber 600D, a first deposition chamber 610D, a second deposition chamber 620D, a third deposition chamber 630D, a fourth deposition chamber 640D, a fifth deposition chamber 650D, and a load lock chamber 660D.

A transfer robot for transferring a substrate 310D is arranged in the transfer chamber 600D. A gate shutter is arranged between the transfer chamber 600D and each chamber. When the gate shutter is open, the spaces of adjacent chambers are continuous. When the gate shutter is closed, the space of adjacent chambers is blocked and the atmosphere of each chamber is individually controllable. The load lock chamber 660D is a chamber that executes the carry-out or the carry-in of the substrate 310D between the sputtering apparatus 10D and the outside.

A target of silicon nitride is arranged in the first deposition chamber 610D. A target of aluminum nitride is arranged in the second deposition chamber 620D. A target of aluminum nitride, a target of gallium nitride, and a target of silicon-doped gallium nitride (N-type semiconductor) are arranged in the third deposition chamber 630D. That is, as shown in FIG. 11A and the like, the third deposition chamber 630D has the same configuration as the sputtering apparatus 10C according to the fourth embodiment. A target of gallium nitride and a target of indium nitride are arranged in the fourth deposition chamber 640D. That is, as shown in FIG. 8A and the like, the fourth deposition chamber 640D has the same configuration as the sputtering apparatus 10A according to the second embodiment. A target of aluminum nitride, a target of gallium nitride, and a target of magnesium-doped gallium nitride (P-type semiconductor) are arranged in the fifth deposition chamber 650D. That is, as shown in FIG. 11A and the like, the fifth deposition chamber 650D has the same configuration as the sputtering apparatus 10C according to the fourth embodiment.

### [5-2. Light-Emitting Element 70D Manufactured Using Sputtering Apparatus 10D]

FIG. 14 is a cross-sectional view showing a light-emitting element manufactured using a sputtering method according to an embodiment of the present invention.

As shown in FIG. 14, the light-emitting element 70D includes a substrate 701D, a barrier layer 702D, a buffer layer 703D, an N-type semiconductor layer 704D, a light-emitting layer 705D, a P-type semiconductor layer 706D, an N-type electrode 707D, and a P-type electrode 708D. The light-emitting element 70D is a so-called LED (Light Emitting Diode), but is not limited to this.

For example, a glass substrate or a quartz substrate can be used as the substrate 701D. For example, a silicon nitride layer or the like can be used as the barrier layer 702D. For example, an aluminum nitride layer or the like can be used as the buffer layer 703D. A silicon-doped gallium nitride layer or the like can be used as the N-type semiconductor layer 704D. A stacked structure in which the indium gallium nitride layer and the gallium nitride layer are alternately stacked can be used as the light-emitting layer 705D. A magnesium-doped gallium nitride layer or the like can be used as the P-type semiconductor layer 706D. A metal such as indium can be used as the N-type electrode 707D. A metal such as palladium or gold can be used as the P-type electrode 708D. The barrier layer 702D may be omitted.

The light-emitting element 70D is manufactured as follows. First, a silicon nitride layer and an aluminum nitride layer are sequentially deposited on the substrate 701D to form the barrier layer 702D and the buffer layer 703D. Next, a silicon-doped gallium nitride layer is deposited on the buffer layer 703D, an indium gallium nitride layer and a gallium nitride layer are alternately deposited thereon, and a magnesium-doped gallium nitride layer is deposited thereon to form the N-type semiconductor layer 704D, the light-emitting layer 705D, and the P-type semiconductor layer 706D.

Subsequently, by a photolithography process, the P-type semiconductor layer 706D, the light-emitting layer 705D, and a portion of the N-type semiconductor layer 704D are etched to expose a portion of the N-type semiconductor layer 704D. By a photolithography process, the N-type electrode 707D is formed on the exposed N-type semiconductor layer 704D. Similarly, the P-type electrode 708D is formed on the P-type semiconductor layer 706D.

In the present embodiment, the N-type semiconductor layer 704D, the light-emitting layer 705D, and the P-type semiconductor layer 706D can be deposited in the same chamber by using the sputtering apparatus 10D. Therefore, it is possible to suppress dust and contaminants from adhering to these interfaces.

In the above-described embodiment, although the configuration in which the target provided in the sputtering apparatus is the rotary target has been exemplified, a flat plate-type target may be used instead of the rotary target.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A sputtering apparatus comprising:
a substrate hold portion configured to hold a substrate;
a first target facing the substrate hold portion;
a second target facing the substrate hold portion and arranged side by side with the first target; and
a partition wall between the first target and the second target,
wherein each of a first normal line in an arbitrary position of the first target and a second normal line in an arbitrary position of the second target is connected to an arbitrary point on the substrate.

2. The sputtering apparatus according to claim 1, wherein
the partition wall is provided to shield a space sandwiched between the first target and the second target.

3. The sputtering apparatus according to claim 1, further comprising:
a first shielding plate between the substrate hold portion and the first target and including a first slit; and
a second shielding plate between the substrate hold portion and the second target and including a second slit.

4. The sputtering apparatus according to claim 3, wherein
the first shielding plate and the second shielding plate are connected to the partition wall.

5. The sputtering apparatus according to claim 3, wherein
the first shielding plate continuously surrounds the first target excluding a region where the first slit is provided, and
the second shielding plate continuously surrounds the second target excluding a region where the second slit is provided.

6. The sputtering apparatus according to claim 3, wherein
the first slit is provided on a side of the second target with respect to a line passing through a rotary axis of the first target among normal lines with respect to the substrate hold portion or the substrate, and
the second slit is provided on a side of the first target with respect to a line passing through a rotary axis of the second target among normal lines with respect to the substrate hold portion or the substrate.

7. A sputtering apparatus comprising:
a substrate hold portion configured to hold a substrate;
a first target facing the substrate hold portion and attached with a first target member; and
a second target facing the substrate hold portion, arranged side by side with the first target and attached with a second target member different from the first target member,
wherein
the first target member contains gallium.

8. The sputtering apparatus according to claim 7, further comprising a partition wall between the first target and the second target.

9. The sputtering apparatus according to claim 8, wherein
the partition wall is provided to shield a space sandwiched between the first target and the second target.

10. The sputtering apparatus according to claim 7, further comprising:
a first shielding plate between the substrate hold portion and the first target and including a first slit; and
a second shielding plate between the substrate hold portion and the second target and including a second slit.

11. The sputtering apparatus according to claim 10, wherein
the first shielding plate and the second shielding plate are connected to the partition wall.

12. The sputtering apparatus according to claim 10, wherein
the first shielding plate continuously surrounds the first target excluding a region where the first slit is provided, and
the second shielding plate continuously surrounds the second target excluding a region where the second slit is provided.

13. The sputtering apparatus according to claim 10, wherein
the first slit is provided on a side of the second target with respect to a line passing through a rotary axis of the first target among normal lines with respect to the substrate hold portion or the substrate, and
the second slit is provided on a side of the first target with respect to a line passing through a rotary axis of the second target among normal lines with respect to the substrate hold portion or the substrate.

14. A sputtering method comprising:
holding a substrate to a substrate hold portion facing a first target and a second target;
forming a stacked structure including a first material of the first target and a second material of the second target by:
depositing the first material of the first target to the substrate by moving the first target and the substrate hold portion relatively while generating plasma for the first target in a first step; and
depositing the second material of the second target to the substrate by moving the second target and the substrate hold portion relatively while generating plasma for the second target in a second step.

15. The sputtering method according to claim 14, wherein
plasma for the second target is stopped when the first material is deposited on the substrate in the first step, and
the first material and the second material are deposited on the substrate by generating plasma for the first target and plasma for the second target in the second step.

16. The sputtering method according to claim 14, wherein
plasma is generated at a position where a first slit is provided by controlling a first magnet included in the first target when the first material is deposited on the substrate, and
plasma is generated at a position where a second slit is provided by controlling a second magnet included in the second target when the second material is deposited on the substrate.

17. The sputtering method according to claim 14, wherein
an amount of a dopant in the second material is greater than an amount of the dopant in the first material, and
a concentration of the dopant contained in a thin film formed on the substrate is adjusted by adjusting an electric power for generating plasma to the second target.
